(19) United States
(12) Patent Application Publication
(10) Pub. No.: US 2013/0049134 A1
(43) Pub. Date: Feb. 28, 2013

(54) SEMICONDUCTOR DEVICE AND METHOD OF MAKING SAME

(71) Applicant: Hiroshi SUNAMURA, Kanagawa (JP)

(72) Inventor: Hiroshi SUNAMURA, Kanagawa (JP)

(73) Assignee: RENESAS ELECTRONICS CORPORATION, Tokyo (JP)

(21) Appl. No.: 13/544,258

(22) Filed: Jul. 9, 2012

Related U.S. Application Data
(60) Provisional application No. 61/529,125, filed on Aug. 30, 2011.

(51) Int. Cl. H01L 27/088; H01L 21/28

(52) U.S. Cl. 257/392; 438/587; 257/E27.06; 257/E21.19

(57) ABSTRACT

In a semiconductor device and a method of making the same, a first transistor has a gate stack comprising an underlying layer formed of a first material and an overlying layer formed of a second material. A second transistor has a gate stack comprising an underlying layer formed of a third material and an overlying layer formed of the second material. A third transistor has a gate stack comprising an underlying layer formed of the first material and an overlying layer formed of a fourth material. A fourth transistor has a gate stack comprising an underlying layer formed of the third material and an overlying material formed of the fourth material. Each of the first through fourth materials has a respectively different work function, so that each of the first through fourth transistors has a respectively different threshold voltage.

### BACKGROUND OF THE INVENTION

1. Field of the Invention

The invention relates to semiconductor devices and methods of making the same. More specifically it relates to devices and methods in which plural transistors are provided with respectively different threshold voltages.

2. Description of Related Art

Semiconductor devices having multiple threshold voltages are conventionally made by utilizing different amounts of dopants in the channel region of the transistor, a technique referred to as channel doping. Channel doping also helps to control short channel effects. However, dopant fluctuations make this technique unattractive for devices in the sub-50 nm technology node. Moreover, in future sub-20 nm devices, fully depleted SOI wafers are likely to be used, so as to provide enhanced gate control to the channel. Extremely thin body SOI transistors and FinFET/Tri-Gate transistors (field effect transistors in which the channel region has a tall and narrow fin-like shape, to permit reduced gate lengths) are regarded as possible candidates.

In fully depleted SOI devices, gate control is sufficiently improved that short channel effects can effectively be suppressed, and hence channel doping can be avoided. An undoped channel region will yield higher mobility, lower threshold voltage and little or no dopant fluctuation. However, the need for multiple threshold voltages will necessitate using dopants in the channel region for at least one of the threshold voltage types, according to conventional techniques.

Using different gate stacks is another way to achieve multiple threshold voltages. For example, U.S. Pat. Pub. No. 2010/0320545 discloses using first and second voltage adjusting layers to produce different threshold voltages for different transistors. U.S. Pat. Pub. No. 2010/0164011 discloses producing a different threshold voltage by forming a cap film in the desired area. U.S. Pat. Pub. No. 2010/0176460 and 2010/0044803 disclose that the oxygen concentration in the gate dielectric film can be used to control threshold voltage. Japanese patent publication JP2011-044580 discloses that nitridation of the gate dielectric using a metal mask is another way. U.S. Pat. Pub. No 2010/0276753 achieves multiple threshold transistors by controlling gate dielectric thicknesses in a process that involves repeated steps of photolithography and etching to predetermined thicknesses for each transistor.

However, conventional techniques for making different gate stacks for nFETs and pFETs have drawbacks in that the gate stack boundary needs to be defined at miniature isolation regions (like STI). Furthermore, making the gate stack more complicated will possibly lower the yield of the devices. It is especially disadvantageous that the conventional gate stack approaches to producing multiple threshold voltages significantly increase the required number of sequences of photolithography and etching. This serves to increase the production cost, lengthen manufacturing time, and decrease output, particularly when more than two masks must be used on the same surface of a gate dielectric film or gate electrode film in order to introduce additional material or produce multiple thicknesses.

### SUMMARY OF THE INVENTION

The present invention provides semiconductor devices in which plural transistors are provided with multiple threshold voltages, without the need for channel doping or complicated gate electrode patterning. The invention also reduces the number of lithographical steps to define the multiple threshold voltage regions, thus making it a cost effective method.

Using this invention, multiple threshold voltages can be achieved and still can gain from the fully depleted nature of the wafers, i.e., higher mobility, lower threshold voltage and reduced (or no) dopant fluctuation.

Thus, in one aspect, a semiconductor device comprises a first transistor having a gate stack comprising an underlying layer formed of a first material and an overlying layer formed of a second material. A second transistor has a gate stack comprising an underlying layer formed of a third material and an overlying layer formed of the second material. A third transistor has a gate stack comprising an underlying layer formed of the first material and an overlying layer formed of a fourth material. A fourth transistor has a gate stack comprising an underlying layer formed of the third material and an overlying material formed of the fourth material. Each of the first through fourth materials has a respectively different work function, and thus each of the first through fourth transistors has a respectively different threshold voltage.

In preferred embodiments of the semiconductor device according to the present invention, the first material is a layer of a nitrided chemical oxide formed on a semiconductor substrate and the third material is a layer of an oxide formed on the semiconductor substrate, the third material being unnitrided or nitrided to a lesser extent than the first material.

In preferred embodiments of the semiconductor device according to the present invention, the second material is a layer of an n work function metal and the third material is a layer of a p work function metal.

In preferred embodiments of the semiconductor device according to the present invention, the gate stack of the first and third transistors does not include a layer of said third material and the gate stack of the second and fourth transistors does not include a layer of the first material.

In preferred embodiments of the semiconductor device according to the present invention, the gate stack of the third and fourth transistors further comprises a layer of the second material.

In preferred embodiments of the semiconductor device according to the present invention, the second material is a high-k dielectric layer doped with atoms of an n work function metal and the fourth material is a high-k dielectric layer doped with atoms of a p work function metal.

In preferred embodiments of the semiconductor device according to the present invention, the first material is a high-k dielectric layer and the third material is a high-k dielectric layer in which vacancies within the third material are filled by oxygen to a greater extent than in the first material.

In preferred embodiments of the semiconductor device according to the present invention, the second material is a high-k dielectric layer and the fourth material is a high-k dielectric layer in which vacancies within the fourth material are filled by oxygen to a greater extent than in the second material.

In preferred embodiments of the semiconductor device according to the present invention, the device includes a fifth transistor having a gate stack comprising an underlying layer formed of the first material and an overlying layer formed of a fifth material; and a sixth transistor having a gate stack comprising an underlying layer formed of the third material and an overlying layer formed of the fifth material. The fifth material has a different work function than each of the first through fourth materials, so that each of the first through sixth transistors has a respectively different threshold voltage.

In another aspect, the present invention relates to a semiconductor device comprising a plurality of transistors each having a high-k dielectric layer underlying a gate and overlying a semiconductor substrate. A first group of the high-k dielectric layers is doped with atoms of an n work function metal, and a second group of the high-k dielectric layers is doped with atoms of a p function work metal. A first subset of each of the first and second groups of high-k dielectric layers has vacancies that are filled by oxygen to a greater extent than in a second subset of each of the first and second groups of high-k dielectric layers. Thus, each of the plurality of transistors comprises a high-k dielectric layer having one of at least four mutually different work functions.

In another aspect, the present invention relates to a semiconductor device comprising a plurality of transistors each having one of at least four mutually different work functions, wherein the gate structures are made by a gate-last technique, and wherein the process and material parameters giving rise to the different work functions are nitridation, oxidation, and selective utilization of p work function and n work function metals.

In another aspect, the present invention relates to a method of making a semiconductor device, comprising depositing a layer of a first material on a semiconductor substrate; modifying selected portions of the first material to create regions of a second material adjoining regions of the first material; depositing a layer of a third material overlying the layer of first material; modifying selected portions of the third material to create regions of a fourth material adjoining regions of said third material; wherein the regions of fourth material and the regions of third material each separately overlap both the regions of first and second material, and wherein the first through fourth materials have respectively different work functions; and etching the layers to isolate gate stack structures each comprising one of the first and second materials as a lower layer and one of the third and fourth materials as an upper layer.

In another aspect, the present invention relates to a method of making a semiconductor device, comprising depositing a region of each of q materials on a semiconductor substrate, wherein q is an integer of 2 or 3; depositing a region of each of r materials overlying the regions of m materials, wherein r is an integer of 2 or 3; wherein each of the q materials and each of the r materials has a respectively different work function from all others of the q and r materials; wherein only one of q and r may equal three; and etching the regions of the q and r materials to form transistor gate stacks each comprising an underlying q material layer and an overlying r material layer; thereby to create transistor gates having at least four threshold voltages.

In another aspect, the gate structures are made by a gate-last technique, to generate at least four, and preferably six or more gate structures having mutually different work functions.

### BRIEF DESCRIPTION OF THE DRAWINGS

Other objects, features and advantages of the invention will become more apparent after reading the following detailed description of preferred embodiments of the invention, given with reference to the accompanying drawings, in which:

FIG. 1 shows in a conceptual way the photolithography requirements for making different gate stacks according to the prior art;

FIG. 2 shows in a conceptual way the reduced photolithography requirements for making different gate stacks according to preferred embodiments of the present invention;

FIGS. 3a-3e show a series of processing steps for making a semiconductor device according to a first embodiment of the present invention;

FIGS. 4a-4e show an ensuing series of processing steps for making a semiconductor device according to the first embodiment of the present invention;

FIGS. 5a-5d show a concluding series of processing steps for making a semiconductor device according to the first embodiment of the present invention;

FIGS. 6a-6c show a series of processing steps for making a semiconductor device according to a variation of the first embodiment of the present invention;

FIGS. 7a-7e show a series of processing steps for making a semiconductor device according to a second embodiment of the present invention;

FIGS. 8a-8d show an ensuing series of processing steps for making a semiconductor device according to the second embodiment of the present invention;

FIGS. 9a and 9b show a concluding series of processing steps for making a semiconductor device according to the second embodiment of the present invention;

FIGS. 10a-10c show a series of processing steps for making a semiconductor device according to a variation of the second embodiment of the present invention;

FIGS. 11a-11d show a series of processing steps for making a semiconductor device according to a fourth embodiment of the present invention;

FIGS. 12a-12d show a series of processing steps for making a semiconductor device according to a sixth embodiment of the present invention;

FIGS. 13a-13c show an ensuing series of processing steps for making a semiconductor device according to the sixth embodiment of the present invention;

FIGS. 14a-14c show an ensuing series of processing steps for making a semiconductor device according to the sixth embodiment of the present invention;

FIGS. 15a-15d show a concluding series of processing steps for making a semiconductor device according to the sixth embodiment of the present invention;

FIGS. 16a-16d show a series of processing steps for making a semiconductor device according to a seventh embodiment of the present invention;

FIGS. 17a-17d show an ensuing series of processing steps for making a semiconductor device according to the seventh embodiment of the present invention;

FIGS. 18a-18d show an ensuing series of processing steps for making a semiconductor device according to the seventh embodiment of the present invention;

FIGS. 19a-19d show an ensuing series of processing steps for making a semiconductor device according to the seventh embodiment of the present invention;

FIGS. 20a-20c show an ensuing series of processing steps for making a semiconductor device according to the seventh embodiment of the present invention;

FIGS. 21a-21c show an ensuing series of processing steps for making a semiconductor device according to the seventh embodiment of the present invention;

FIGS. 22a-22c show an ensuing series of processing steps for making a semiconductor device according to the seventh embodiment of the present invention;

FIG. 22d is a detail of the region XXIId in FIG. 22c;

FIGS. 23a-23c show an ensuing series of processing steps for making a semiconductor device according to the seventh embodiment of the present invention;

FIGS. 24a and 24b show a concluding series of processing steps for making a semiconductor device according to the seventh embodiment of the present invention; and

FIG. 24c shows a schematic layout view of the seventh embodiment of the present invention.

### DETAILED DESCRIPTION OF PREFERRED EMBODIMENTS

The invention will be now described in greater detail with reference to various preferred embodiments thereof. Those skilled in the art will recognize that many alternative embodiments can be accomplished using the teachings of the present invention and that the invention is not limited to the embodiments illustrated for explanatory purposes.

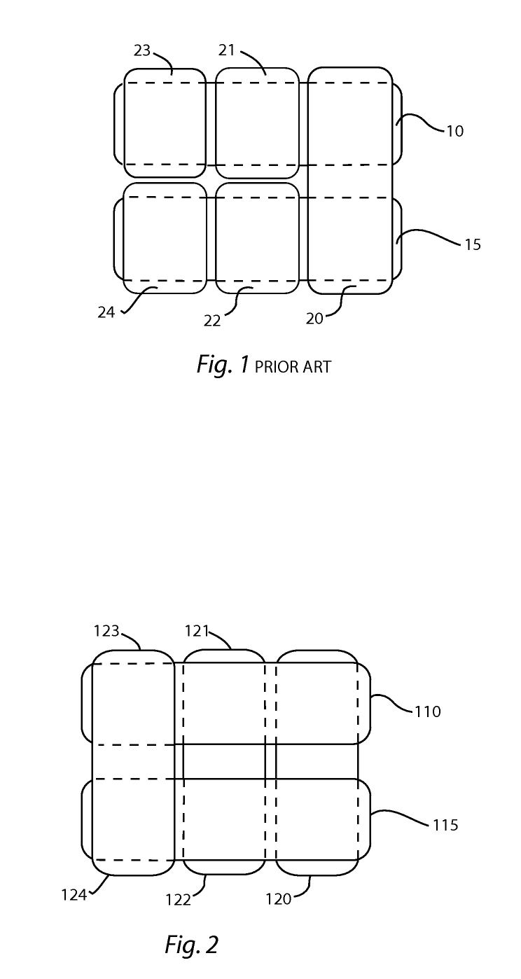

With reference to FIG. 1, a conventional gate stack approach to providing multiple threshold voltages is shown in an explanatory manner. The metal gate definition for an nFET and a pFET (regions 10 and 15 in FIG. 1) requires one photolithographic mask, and a further photolithographic mask is required to define each of the high threshold voltage regions 21-24 so that each region can be selectively doped. In this example, three different threshold voltage regions for each of the nFET and pFET regions 10 and 15 will require at least a first mask (for the metal gates), plus four further masks for to create the regions 21-24, for a total of five photolithography processes.

Referring now to FIG. 2, the same number of different threshold voltages is produced according to preferred embodiments of the present invention using two fewer photolithography processes, because layers 125-128 of materials having respectively different work functions from one another are formed so as to overlap with each of the nFET and pFET regions 110 and 115. Thus, in the case of FIG. 2, three different threshold voltage regions each for each of the nFET and pFET regions can be produced using one mask for the metal gates, and only two masks for the layers 125-128, for a total of three photolithographic processes.

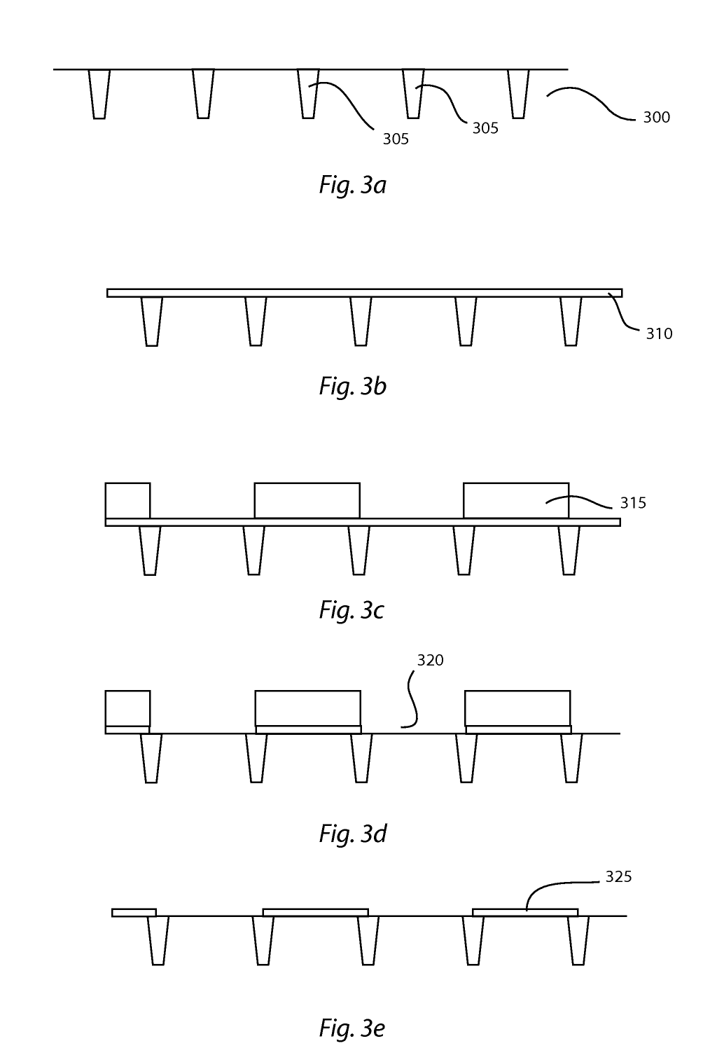

A first embodiment of the method and device according to the invention is made as shown starting with FIG. 3a, by a process that begins by forming isolation regions 305, such as shallow trench isolation regions (STI), in a semiconductor substrate 300, which is preferably a silicon substrate. Substrate 300 may be monolithic or composite, for example an SOI (silicon on insulator) substrate.

Alternative materials for the substrate 300 include germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials.

Shallow trench isolation structures 305 are formed from a dielectric material and are preferably silicon dioxide. Silicon nitride, silicon oxynitride and combination thereof are alternative possibilities.

As noted above, the substrate 300 need not be doped in its channel region, with a fully depleted substrate being preferred. However, doped substrates are also within the scope of the present invention, and the techniques and structures described herein may be used to advantage in appropriate applications in combination with channel doping.

As shown in FIG. 3b, a gate oxide layer 310 is then formed in a conventional manner on substrate 300. Next, as shown in FIG. 3c, a first photomask 315 is formed on the oxide layer 310, so as to cover certain regions of the oxide layer and to expose other regions of the oxide layer.

Photomask 315 is depicted schematically as a single layer; however in practice it may be formed of one or a plurality of layers, as is known to those skilled in the art. For example, mask 315 may be a tri-mask composed of a photoresist layer, an SiARC layer (Si-based Anti-Reflection Coating layer) or LTO (Low Temperature Silicon Oxide) and an organic planarization layer (OPL). These observations regarding mask 315 apply also to all other masks described herein.

FIG. 3d shows the structure following a wet etch to remove oxide layer 310 in the areas where it had been exposed through mask 315, to reveal regions 320 of the underlying substrate 300. The mask 315 is then removed by resist stripping as shown in FIG. 3e, to leave regions 325 of the oxide layer 310 that had been covered by the mask.

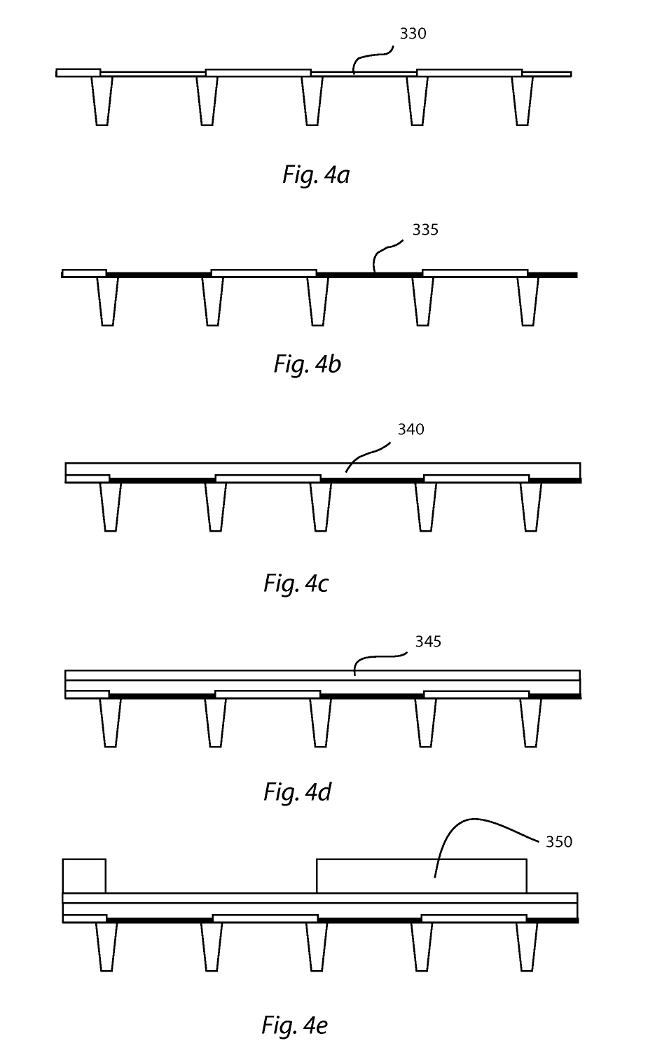

That structure is then treated as depicted in FIG. 4a to form a thin chemical oxide layer 330 on the exposed regions 320 of substrate 300. In the case of a silicon substrate, the chemical oxide may for example be an oxide of the type that grows on silicon surface during wet cleaning and rinsing operations. Such oxides are typically relatively highly hydrated with a composition departing from that of stoichiometric SiO₂, i.e., SiOₓ where x<2. Chemical oxide 330 can be formed for example by heating in a furnace or by treatment with a chemical solution.

The thickness and composition of chemical oxide layer 330 is selected such that it more readily undergoes nitridation than oxide layer 310. As shown in FIG. 4b, the device then undergoes nitridation either in a furnace or by plasma nitridation, to generate nitrided regions 335. These nitrided regions 335 possess a different work function than the regions 325 of oxide layer 310 that remain in the device, because regions 325 are either not nitrided or are nitrided to a significantly lesser extent than regions 335.

Next, as shown in FIG. 4c, a high-K layer 340 is formed so as to cover both the nitrided regions 335 and the residual oxide regions 325. High-k layer 340 is formed from a material having a high dielectric constant relative to silicon dioxide. The dielectric constant of layer 340 is preferably greater than 8.0. Layer 340 is preferably an oxide or oxynitride film that includes one or more of Hf, Zr, Ti and Al, with Hf and/or Zr being particularly preferred. Films including HfO₂, HfSiO, and/or HfSiON are also preferred.

High-k layer 340 may be formed according to methods known in the art, including, for example, chemical vapor deposition (CVD), atomic layer deposition (ALD) and physical vapor deposition (PVD).

Then, as shown in FIG. 4d, a layer 345 of a p work function metal is deposited on the high-k layer 340. The p work function metal is a metal or a conductive metal alloy having a relatively high work function (for example approximately 5.3 eV) such that it is suitable for use in p-MOS devices. Preferred materials for layer 345 include Al, Ti, Ta, Ge and combinations and alloys of these.

Next, as shown in FIG. 4e, a further photo mask 350 is formed on layer 345, so as to cover part of layer 345 and to expose another part of layer 345. It will be seen in FIG. 4e that each of the regions covered and exposed by photo mask 350 includes both nitrided regions 335 and residual oxide regions 325 in the layer underlying the p work function metal layer 345 and the high-k layer 340.

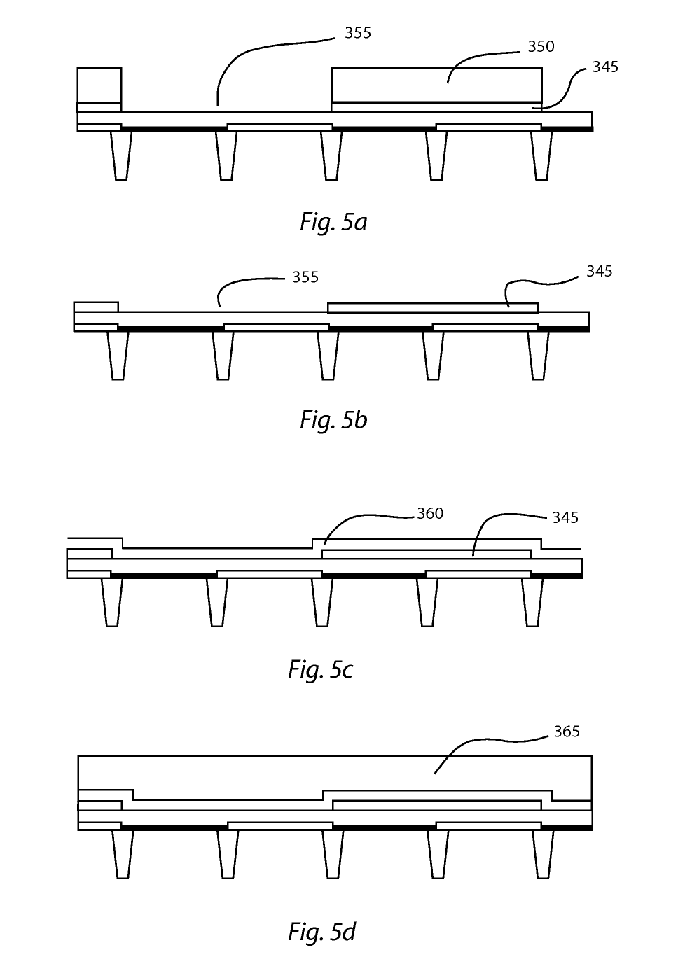

Turning now to FIG. 5a, the p work function metal layer 345 is then wet etched through the mask 350, to expose the underlying high-k layer 340 in the regions 355 not covered by mask 350. This etch may be a dry etch or a wet etch; in either case, the etch is preferably selective to the material of the high-k layer 340, so that the high-k layer 340 is not removed to any significant extent.

Mask 350 is then removed by photoresist stripping as shown in FIG. 5b, whereupon an n work function metal 360 is deposited as shown in FIG. 5c so as to cover both the remaining portions of p work function metal 345 and the exposed areas of high-k layer 340. The n work function metal is a metal or a conductive metal alloy having a relatively low work function (for example approximately 3.9 eV) such that it is suitable for use in n-MOS devices. Preferred materials for layer 360 include La, Lu, Sc, Y and combinations and alloys of these.

Finally, a metal gate 365 is deposited overlying the previously-described gate stack, to complete the gate layer formation. The gate layers can thereafter be etched as described in connection with the ensuing embodiments, to form gate stacks that are separated from one another.

It will be appreciated that the method and device according to this first embodiment of the present invention creates transistors having one of four different threshold voltages, owing to the mutually different work functions of the materials 325, 335, 345 and 360. In particular, a first transistor threshold voltage is provided by the layer 360 overlying a layer 335; a second transistor threshold voltage is provided by the layer 360 overlying a layer 325; a third transistor threshold voltage is provided by the combined layers 345 and 360 overlying another layer 335; and a fourth transistor threshold voltage is provided by the combined layers 345 and 360 overlying another layer 325.

However, only two photolithography masks are needed to create these four different threshold voltages.

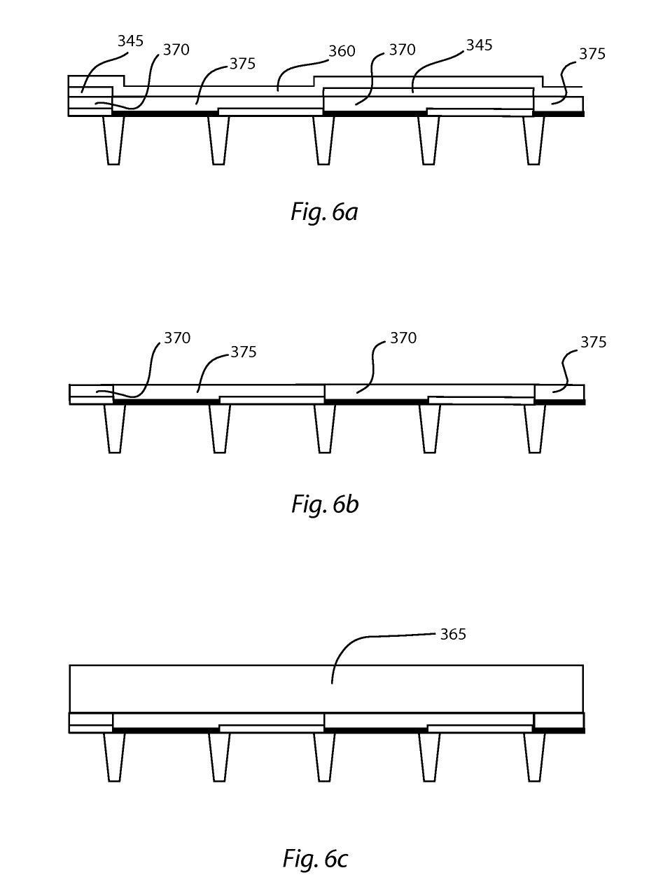

A variation of the first embodiment is illustrated in FIGS. 6a-6c. In particular, in the first embodiment, the difference in threshold voltages in the overlying layers is produced by utilizing only layer 360 in some regions and the combination of layers 345 and 360 in other regions; however, that structure can result in a step difference between those regions, which can be a complication to overall device fabrication.

Therefore, in FIG. 6a, the structure depicted in FIG. 5c has been subjected to optional annealing, such that atoms of the p work function metal in layer 345 diffuse into the underlying high-k dielectric layer to create regions 370 of p-metal doped high-k dielectric layer, whereas atoms of the n work function metal in layer 360 diffuse into the underlying high-k dielectric layer to create regions 375 of n-metal doped high-k dielectric layer. This annealing is preferably performed at a temperature of at least 800° C.

Following annealing, the metal layers 345 and 360 themselves can be removed, e.g. by a wet etch process or a CMP process, to leave only the differentiated regions 375 and 370 as shown in FIG. 6b, which now reside in the same plane.

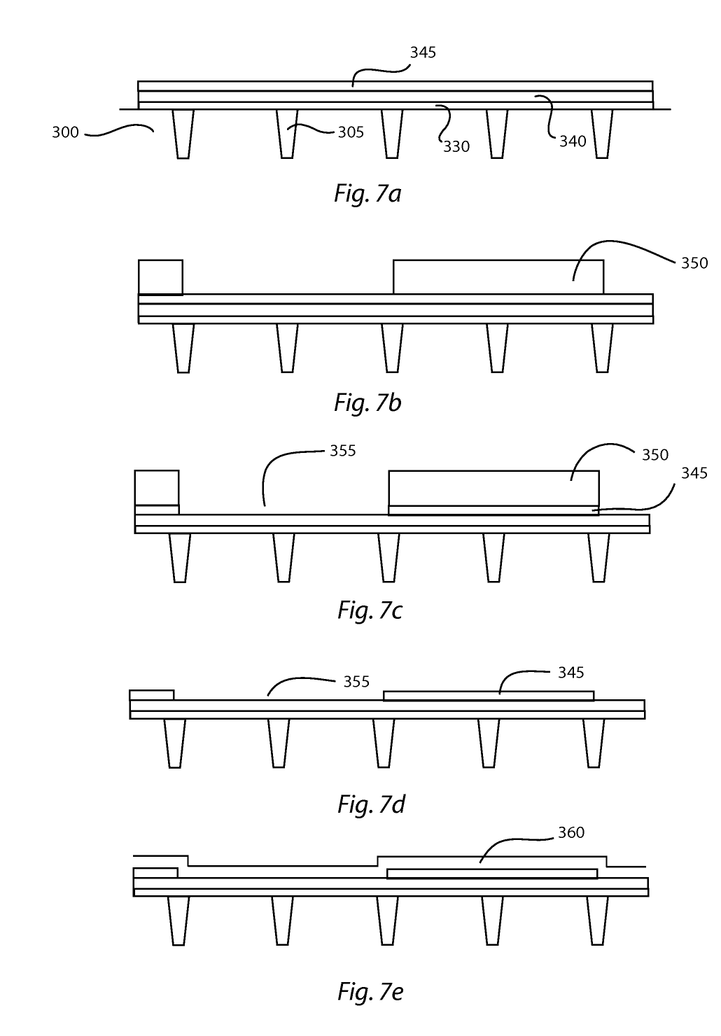

Turning now to FIG. 7a, in a second embodiment of the present invention the oxide layer 310 is not formed, and instead a thin chemical oxide layer 330 is formed continuously on the upper surface of substrate 300. The high-k dielectric layer 340 is deposited on the continuous chemical oxide layer 330, followed by deposition of the p work function metal layer 345 as described above in connection with the first embodiment.

Patterning of layer 345 by photolithography then proceeds as described in connection with the first embodiment, as shown in FIGS. 7b and 7c, to expose regions 355 of the high-k dielectric layer 340, whereafter the photomask 350 is removed (FIG. 7d) and a layer 360 of n work function metal is deposited so as to cover the layer 345 and the exposed regions 355 (FIG. 7e).

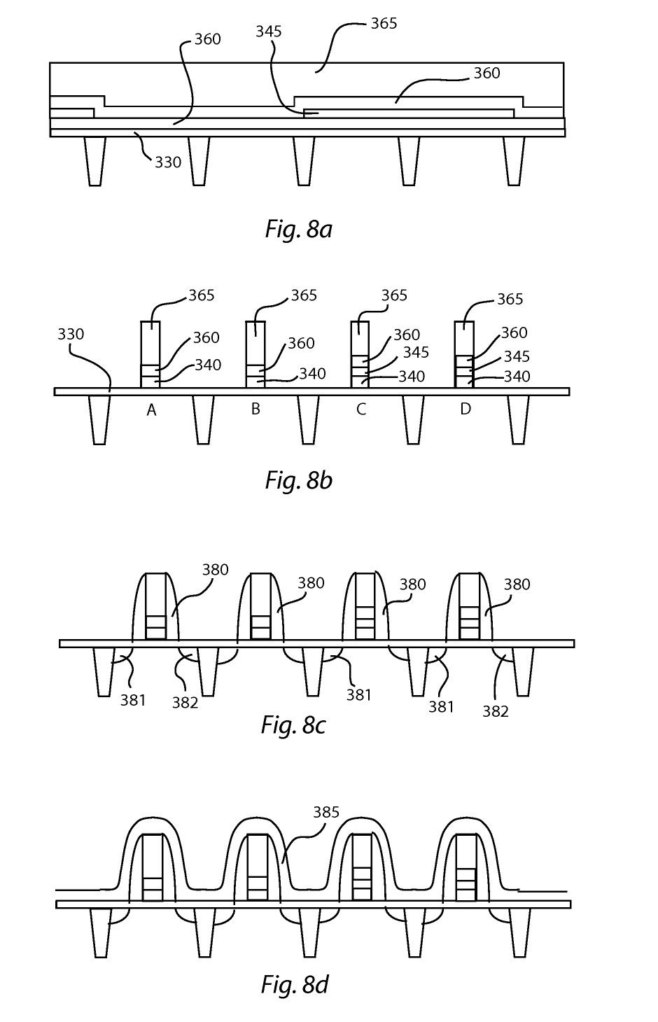

Layer 365 of gate metal is then deposited (FIG. 8a), followed by a dry etch of all of the layers overlying the oxide layer 310, so as to form individual gatestacks A, B, C and D, as shown in FIG. 8b. At this stage it will be noted that gatestacks A and B do not differ from one another as to work function and hence as to threshold voltage, and, similary, gatestack C and D, although different from gatestacks A and B, are not different from one another.

Gate sidewalls 380 and source/drain regions 381, 382 are then formed as depicted in FIG. 8c, by conventional processes including rapid thermal annealing (RTA). Next, as shown in FIG. 8d, an oxygen supply film 385 is formed to cover all of the transistors A-D. Oxygen supply layer 385 is preferably formed by chemical vapor deposition (CVD) using a source gas including ozone and Si ions.

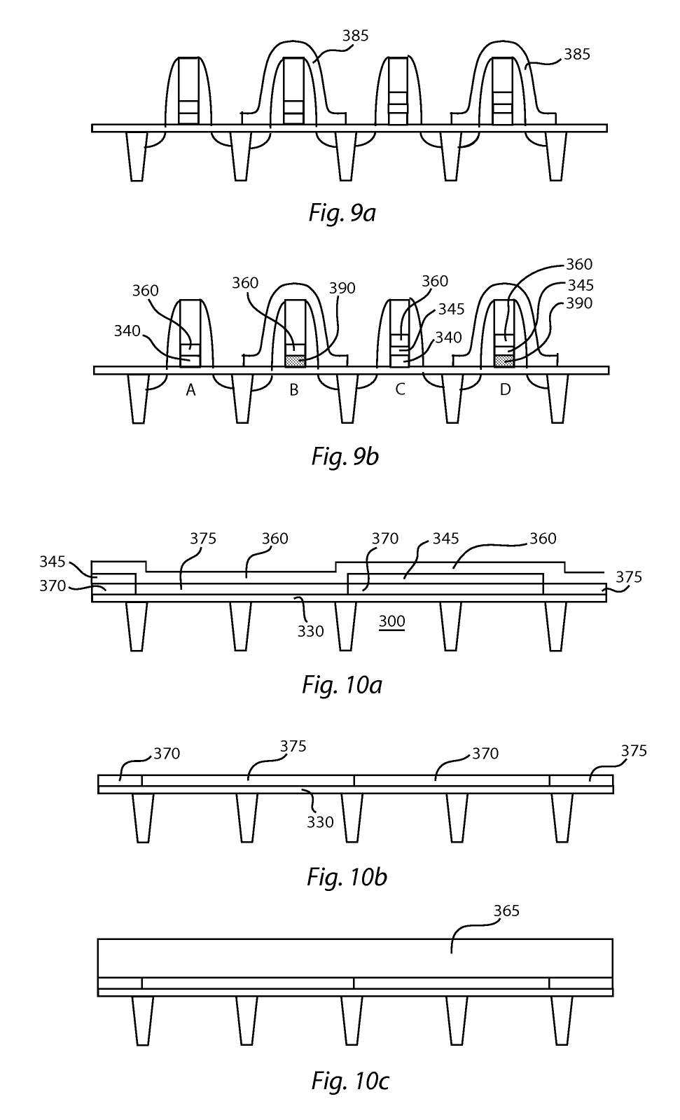

Next, as shown in FIG. 9a, lithography and wet etching is performed so as to remove film 385 from some of the transistors, while leaving the film on other transistors. In particular, FIG. 9a shows film 385 removed from transistors A and C, while it remains on transistors B and D. Thus, with reference to the underlying materials some of the 340/360 gate stacks remain covered with film 385 while the remaining 340/360 gate stacks are uncovered; and, similarly, some of the 340/345/360 gate stacks remain covered with film 385 while the remaining 340/345/360 gate stacks are uncovered.

Annealing is then performed, preferably at a temperature in the range of 400-600° C., with causes oxygen atoms from the remaining layer portions 385 to diffuse into the high-K dielectric layer of the corresponding gate stacks, as shown in FIG. 9b. This causes vacancies in the high-K regions 390 that had been covered by layer 385 to be filled by oxygen atoms to a greater extent than for the high-K regions 340 that were not covered by the oxygen supply layer 385. Layers 390 resulting from this processing stage therefore differ in their work function from untreated layers 340; consequently, the transistors A-D as shown in FIG. 9b now have work functions that differ from one another, and hence provide four different threshold voltages.

Again, however, only two additional lithography processes are required for this embodiment, relative to a single threshold voltage semiconductor device.

In the variation shown in FIGS. 10a and 10b, the structure depicted in FIG. 7e is subjected to thermal annealing as described above in connection with FIGS. 6a-6c, so as to create regions 370 of p-metal doped high-k dielectric layer, and regions 375 of n-metal doped high-k dielectric layer, but in this embodiment overlying a continuous chemical oxide layer 330. Processing then continues as described in connection with FIGS. 8b-8d and FIGS. 9a and 9b, to again create transistors A-D having four different threshold voltages, but without the step difference associated with the overlapping layers 360 and 345.

In a third embodiment of the method and device according to the present invention, a semiconductor substrate is processed as described above in connection with FIGS. 3a-3d, FIGS. 4a-4e and 5a-5d, followed by dry etching to form individual gate stacks whose layer compositions are 335/340/360/365, 325/340/360/365, 335/340/345/360/365 and 325/340/345/360/365. In this third embodiment, however, at least one of these four types of gate stacks, and preferably two of these gate stack types, and possibly also all four of these gate stack types, are then further processed according to the technique described above in connection with FIGS. 8c and 8d and FIGS. 9a and 9b, such that the high-k layer 340 of half of the transistors in each of the further processed gate stack types is converted to a layer 390 as described above. Consequently, in this third embodiment, from five to eight total threshold voltages can be created, utilizing only three additional lithography processes relative to a single threshold voltage device.

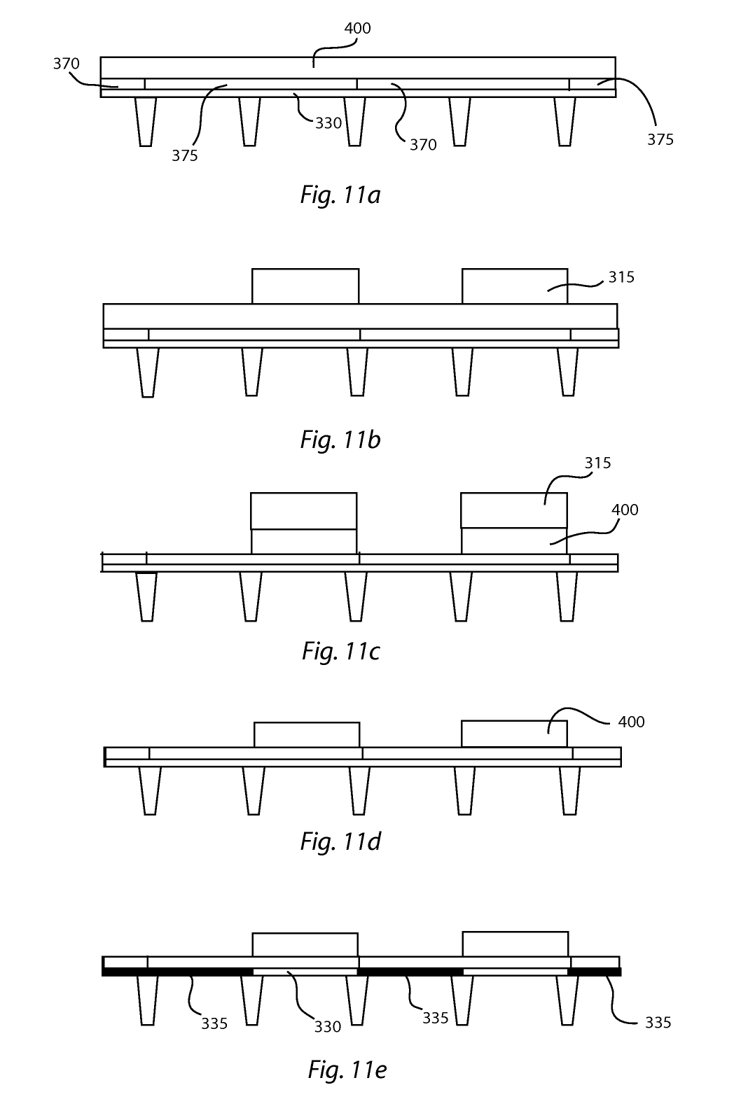

Referring now to FIG. 11a, which describes a fourth embodiment of the method and device according to the present invention, the structure is similar to that depicted in FIG. 10b, except that the structure as shown in FIG. 11a has been covered not with a metal gate 365 but rather with a metal cover 400 that serves to protect the chemical oxide layer 330 from subsequent nitridation.

Metal cover 400 is then patterned using a photomask 315 as described above in connection with the first embodiment, followed by removal of the mask 315 by photoresist stripping (FIGS. 11b-11d). The structure depicted in FIG. 11d is then subjected to nitridation as described in connection with the first embodiment, which serves to nitride those regions of chemical oxide layer 330 not covered by the patterned metal cover, through the high-K layer 340. The patterned metal cover is then removed, resulting in a structure similar to that depicted in FIG. 6b, but which has been produced by a different series of process steps, and without the need to form the oxide layer 310. A metal gate layer 365 is then added as depicted in FIG. 6c.

A fifth embodiment according to the present invention proceeds according to the fourth embodiment as described above. Then, following etching of the of the gate layers to produce individual gate stacks, the gate stacks are further processed as described in connection with FIGS. 8c and 8d and FIGS. 9a and 9b, to convert half of the high-K layers 340 in one or more of the four transistor groups into an oxygen-enriched layer 390 as described above. In this way, one further photolithography process can be leveraged to add from one to four additional threshold voltages to the device.

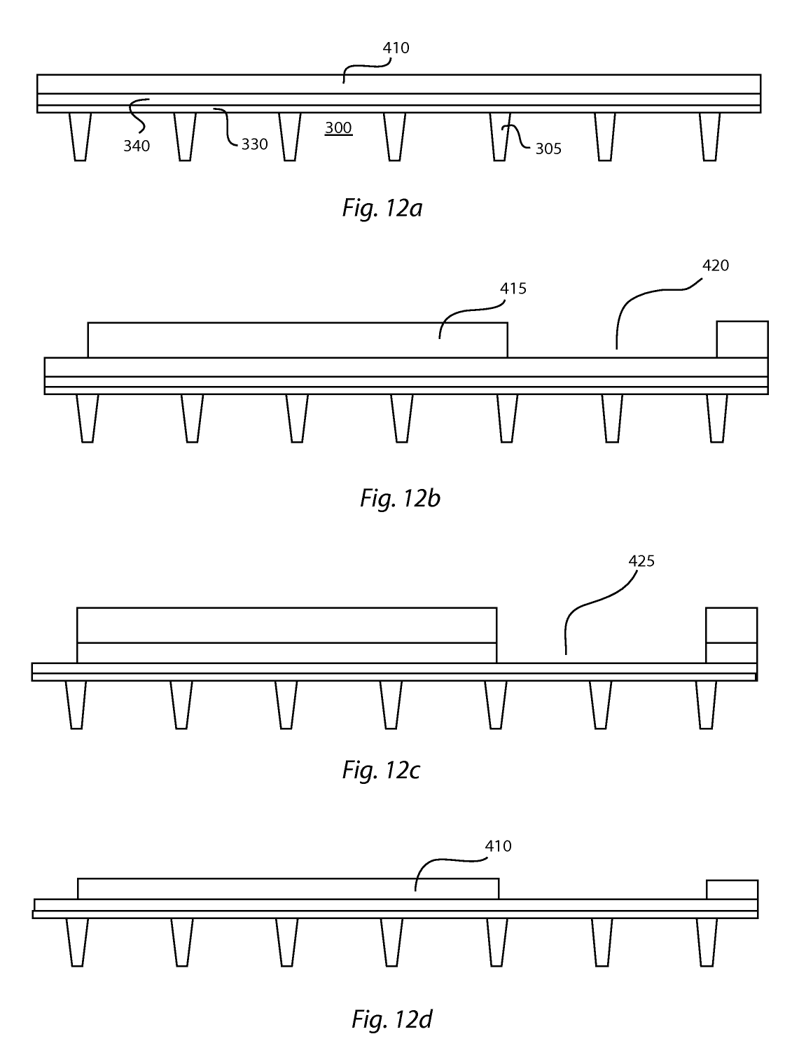

In a sixth embodiment according to the present invention, as depicted beginning with FIG. 12a, a silicon substrate 300 provided with STI isolation elements 305 has a chemical oxide layer 330 formed on the surface of the substrate, and a high-K dielectric layer formed on the layer 330, as described in connection with several of the foregoing embodiments.

On the high-K dielectric layer 340 there is formed a diffusion-limiting metal cap layer 410. Layer 410 is formed from a material that will serve to limit diffusion of atoms of an overlying layer into an underlying layer, as will be described below. Preferred materials for the cap metal diffusion controlling film include Ti, Ta, W, TiN, TaN, WN, TiC, TaC and WC. The thickness of film 410 is not particularly limited; however, a relatively thin film of from 5 to 30 Å is preferred, in which case the film is suitably formed by atomic layer deposition (ALD).

Next, as shown in FIGS. 12b-12d, the metal film 410 is patterned using photomask 415, which covers the film 410 in selected regions while exposing the film 410 in other areas 420. A wet etch as described in connection with the foregoing embodiments removes film 410 in regions 420 so as to expose corresponding regions 425 of the high-K dielectric film 340, after which the mask 415 is removed by photoresist stripping.

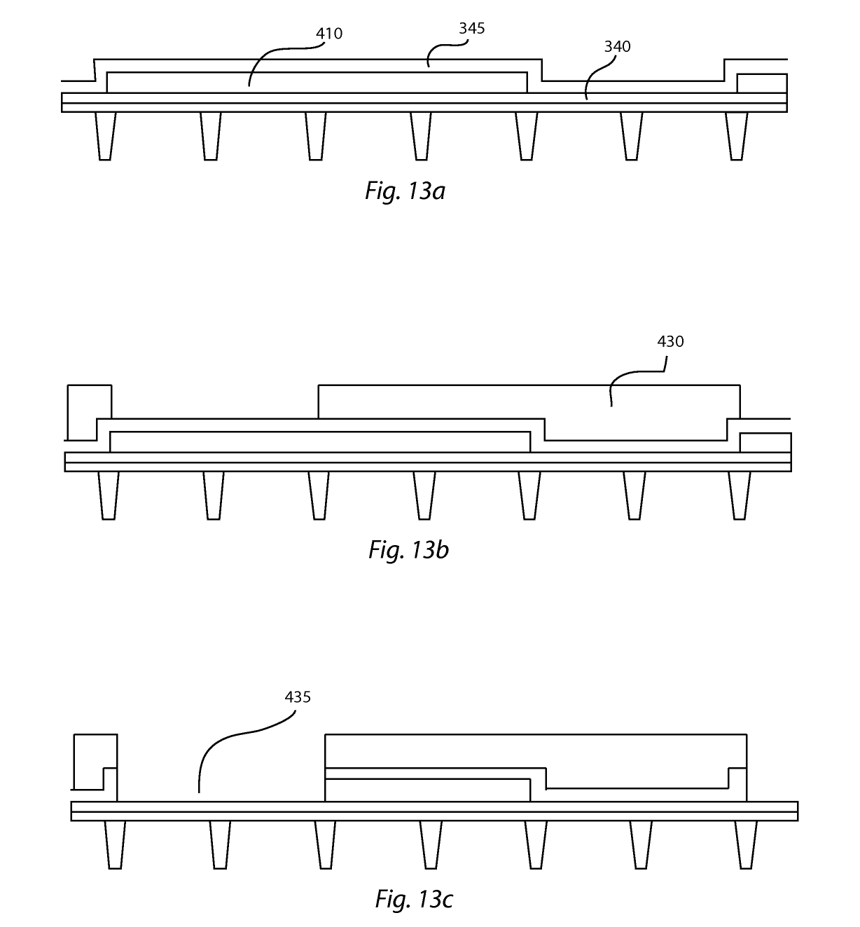

Then, as shown in FIG. 13a, a layer of a p work function metal 345 as described in the foregoing embodiments is deposited on the cap metal diffusion controlling film 410 and on the exposed regions 425 of the high-K dielectric film 340. A further lithography process is performed by forming a photomask 430 on the p work function metal layer 345, followed by wet etching of the regions exposed through mask 430 to expose regions 435 of the underlying high-K dielectric layer 340, as shown in FIGS. 13b and 13c.

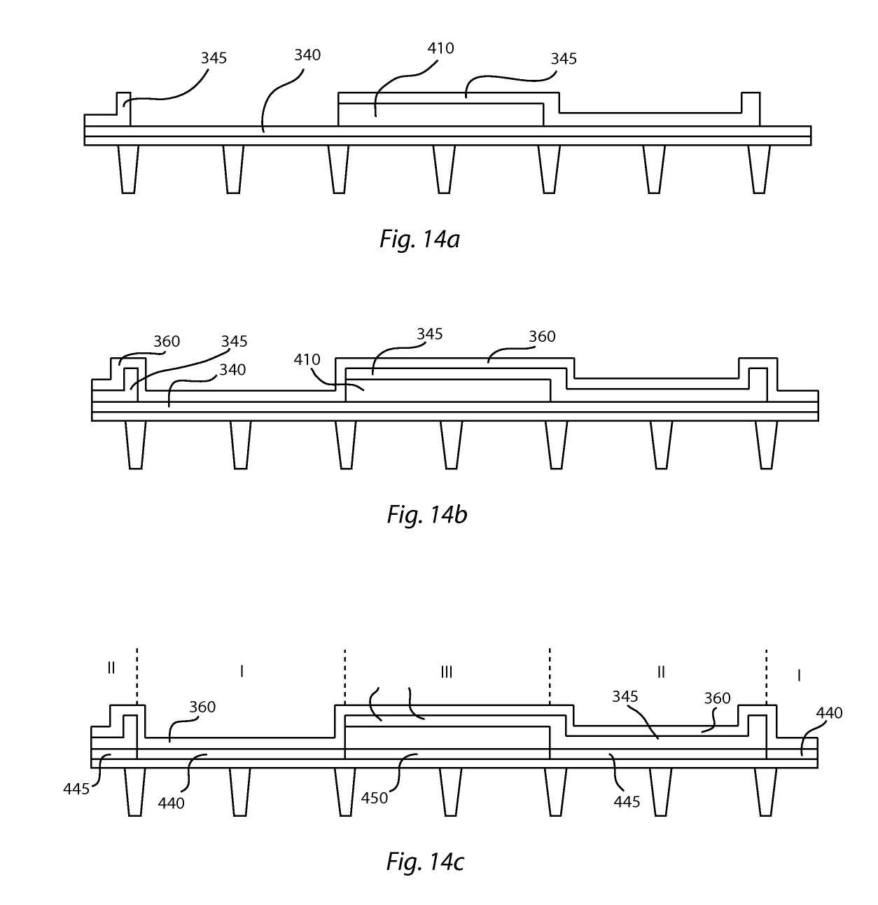

Photomask 430 is then removed by photoresist stripping to expose the patterned p work function metal layer 345, as shown in FIG. 14a, whereupon a layer of n work function metal 360 as described above is formed to cover the patterned p work function metal layer 345 and the exposed regions 435 of the underlying high-K dielectric layer 340, as shown in FIG. 14b.

Next, the structure depicted in FIG. 14b is subjected to thermal annealing as described above in connection with FIGS. 6a-6c, which causes differentiated diffusion of metal ions into the underlying high-K dielectric layer 340, in the regions I-III denoted in FIG. 14c. In particular, in regions I, ions of the n work function metal 360 migrate unimpeded into the high-K dielectric layer 340, to form doped regions 440. Similarly, in regions II, ions of the p work function metal 345 migrate unimpeded into the high-K dielectric layer 340, to form doped regions 445.

In regions III, metal cap layer 410 serves to limit the diffusion of the p work function metal 345 relative to regions II, so as to create a region suitable for forming mid-gap transistors whose performance will be intermediate that of the nFET and pFET transistors to be formed from regions I and II.

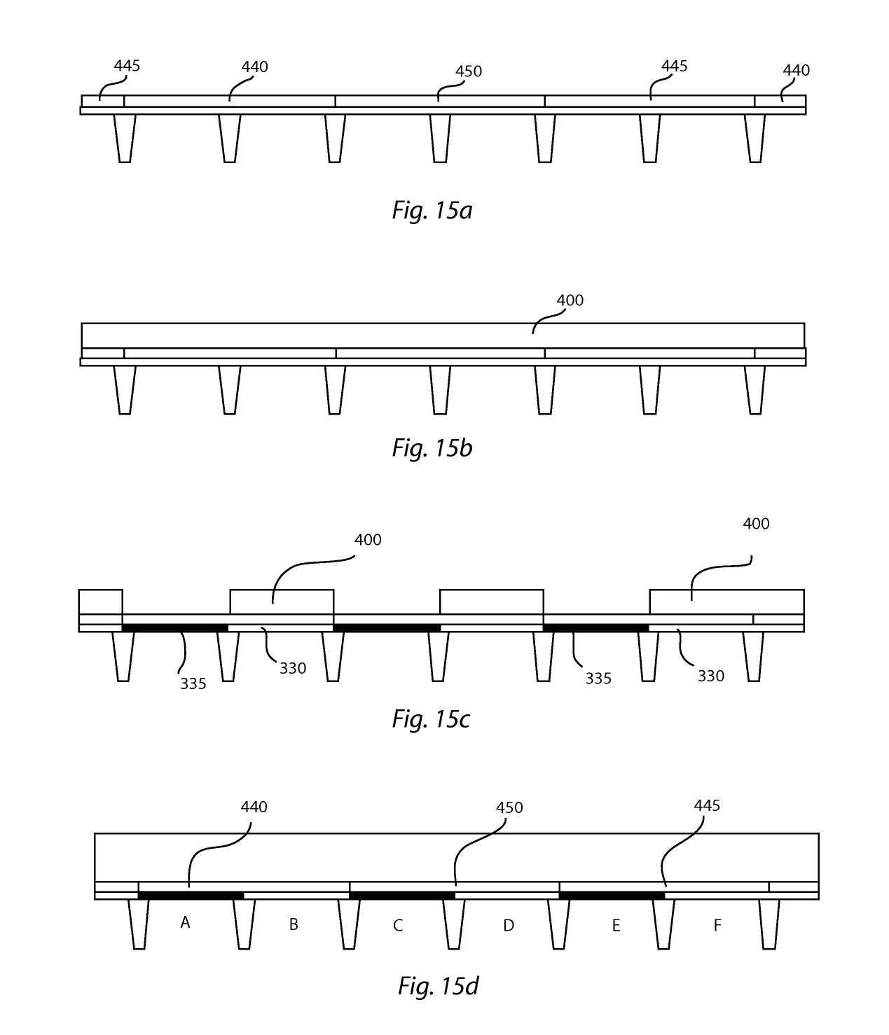

Layers 410, 345 and 360 are then removed, for example by wet etching or CMP, to expose regions 440, 445 and 450 of high-K dielectric layer, as shown in FIG. 15a. A metal cover 400 is then formed as described above, followed by patterning and nitriding as described in connection with FIGS. 11a-11e to create regions 335 and 330 underlying each of the regions 440, 445 and 450, as shown in FIGS. 15b and 15c.

After removal of the patterned metal cover 400 and deposition of a metal gate layer 365, as shown in FIG. 15d, there are formed six different gate threshold structures A-F.

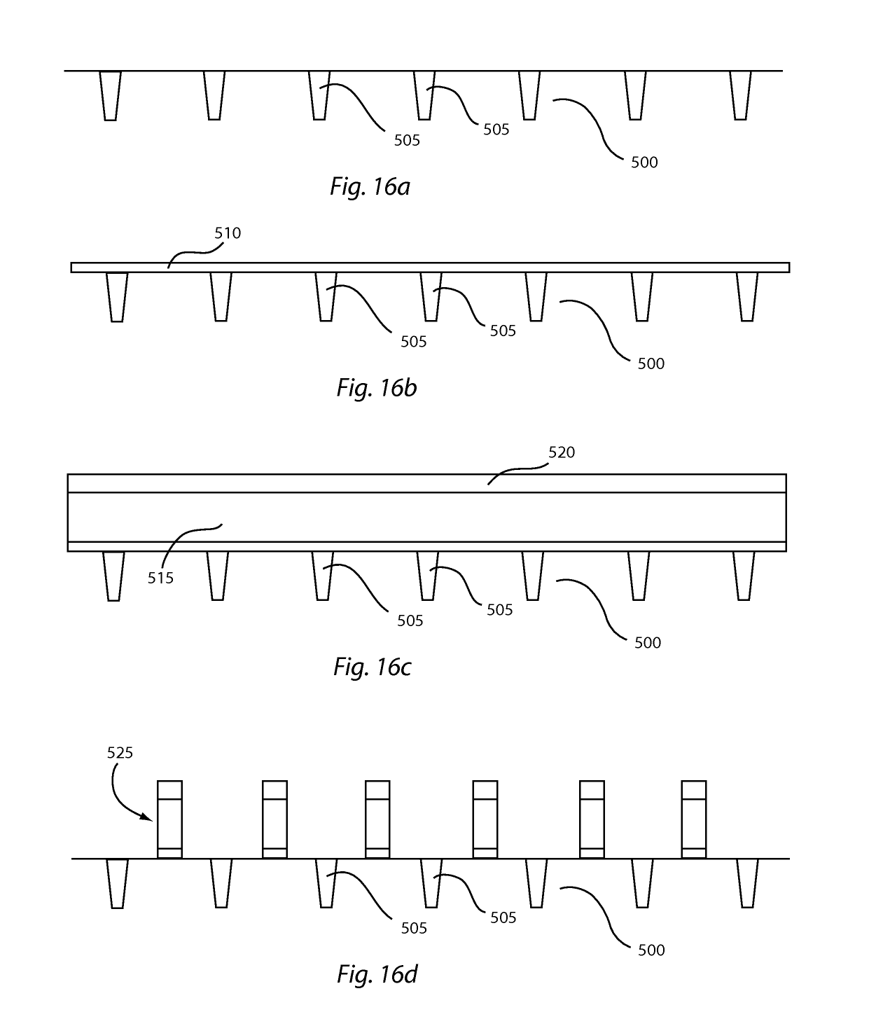

FIGS. 16-24 depict a device and method according to a seventh embodiment of the present invention, wherein the semiconductor devices are formed by a gate last technique.

In particular, FIG. 16a shows a semiconductor substrate 500 and STI isolation regions 505 formed therein, as described in connection with various of the preceding embodiments. The substrate 500 is treated so as to form a dummy oxide layer 510, as shown in FIG. 16b. Next, a layer of dummy polysilicon 515 and an overlying hard mask 520 are formed as shown in FIG. 16c. Following dry etching, a series of dummy gate stacks 525 are formed, as shown in FIG. 16d.

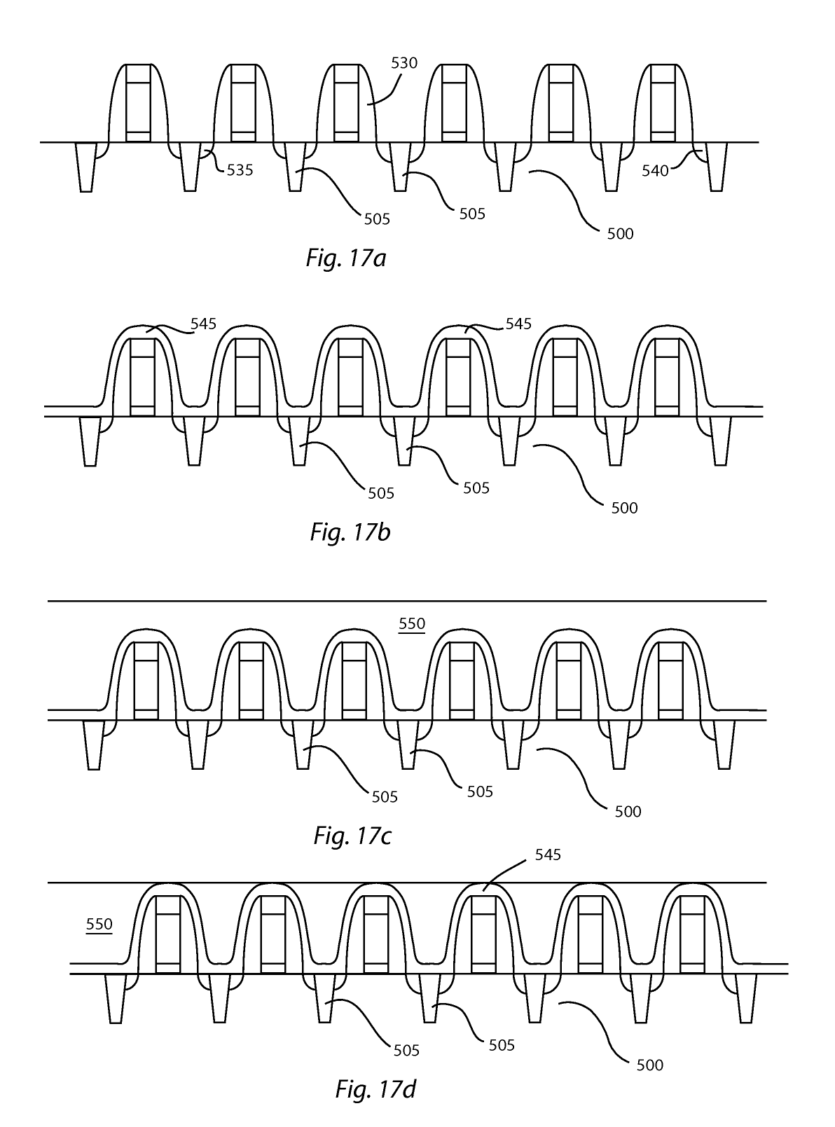

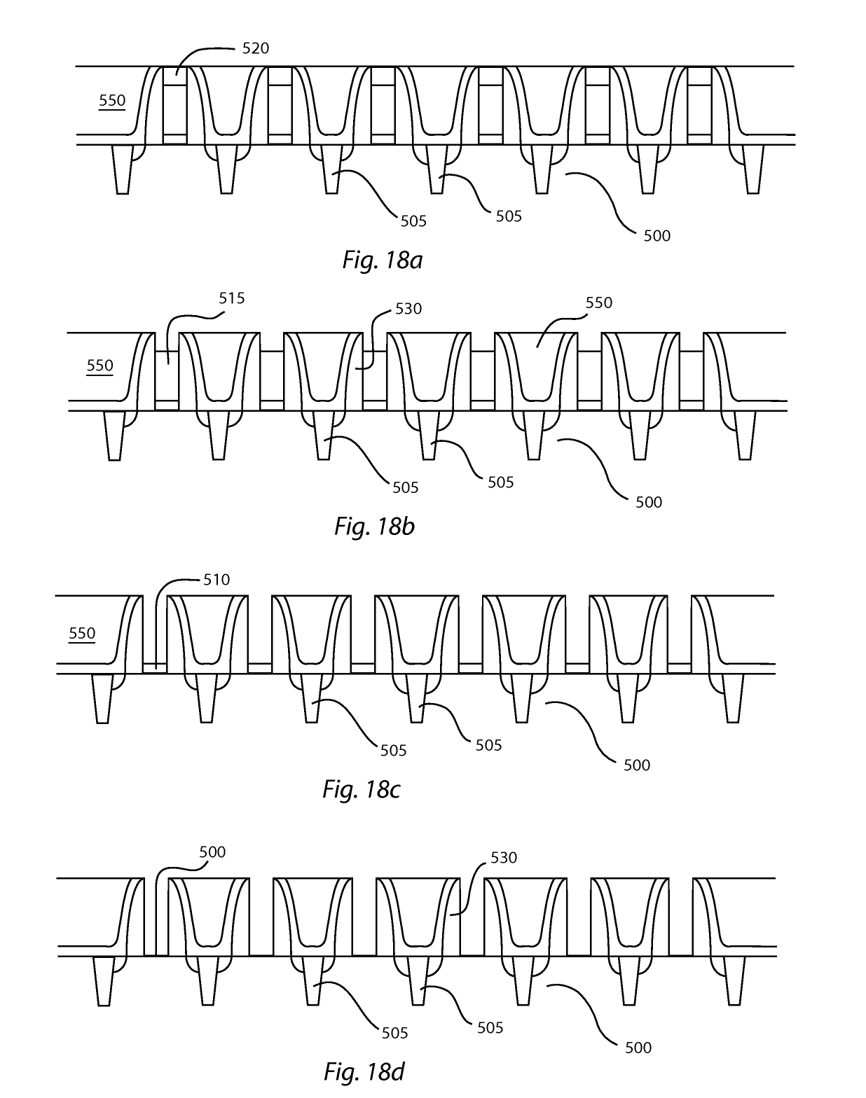

Gate sidewalls 530 and source/drain regions 535, 540 are then formed as depicted in FIG. 17a, by conventional processes including rapid thermal annealing (RTA). A liner of silicon nitride 545 is then formed so as to cover the dummy gates, sidewalls 530 and the exposed surfaces of the substrate 500, as shown in FIG. 17b, followed by deposition of an interlayer dielectric layer 550 as shown in FIG. 17c, which is planarized by a first stage of chemical mechanical polishing (CMP). A second stage of CMP is then performed so as to bring the upper surface of the interlayer dielectric layer 550 down to the level of the topmost regions of the SiN liner 545.

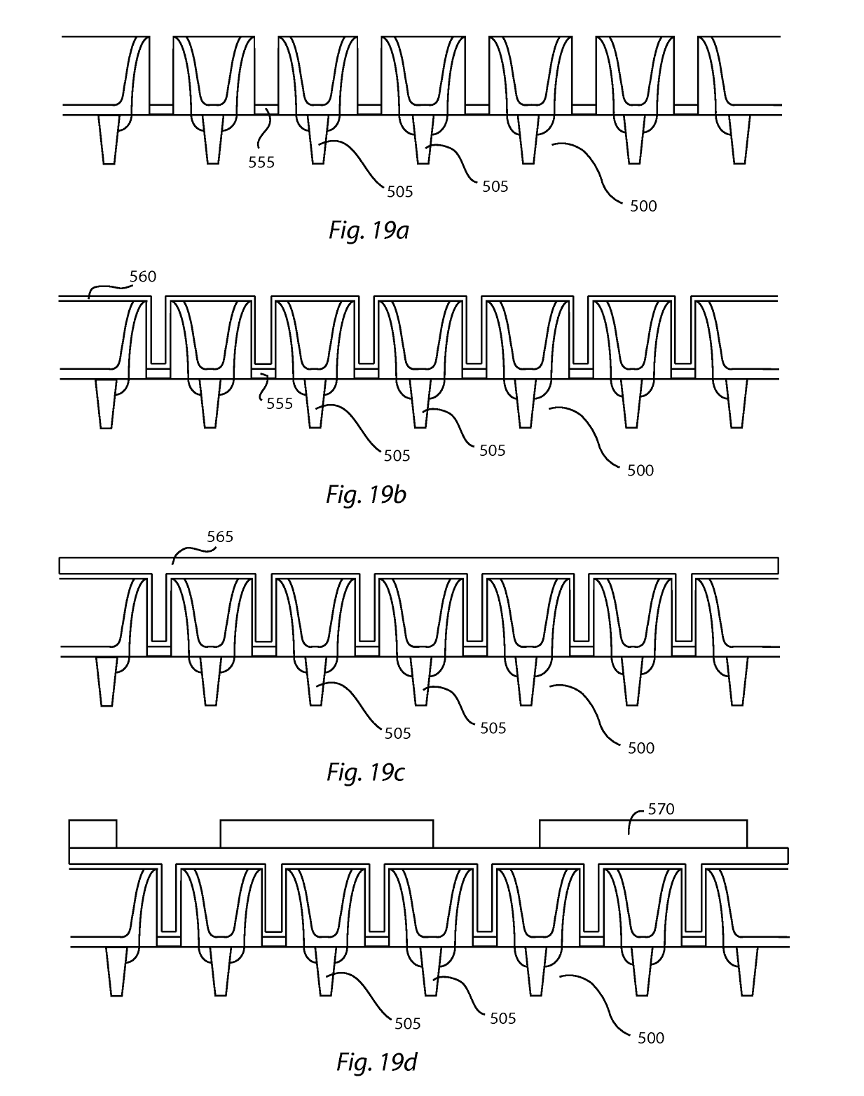

Next, as shown in FIG. 18a, a third stage of CMP is performed so as to bring the upper surface of the interlayer dielectric layer 550 down to the level of the upper surfaces of the hard mask 520 on the dummy gates 525. The hard mask 520 is then opened by a conventional technique (FIG. 18b), followed by removal of the dummy polysilicon 515 (FIG. 18c) and removal of the dummy oxide 510 (FIG. 18d), so as to expose the underlying silicon substrate 500 in the regions formerly occupied by the dummy gates, while preserving the gate sidewalls 530 and the interlayer dielectric layer 550 in the other regions of the device.

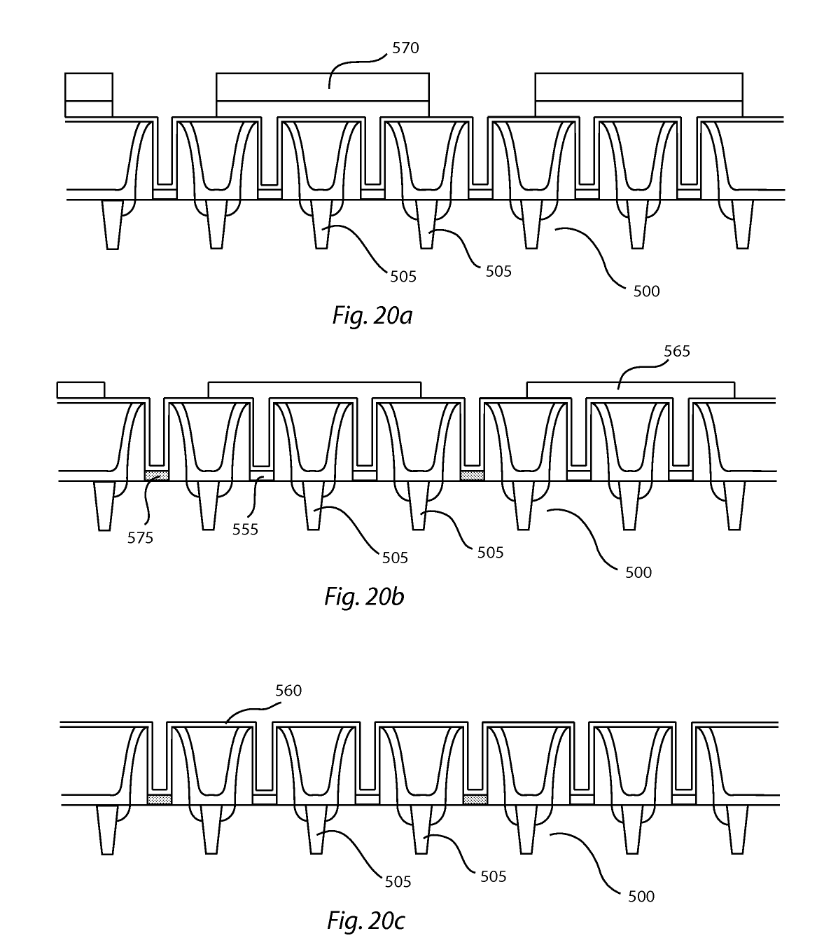

As shown in FIG. 19a, the exposed regions of the substrate 500 are then oxidized so as to form insulating layer 555, followed by formation of a high-K dielectric film 560 that covers all of the exposed surfaces depicted in FIG. 19b, the high-K film 560 being as described in connection with the preceding embodiments. Next, as shown in FIG. 19c, a blocking film 565 is deposited over the high-K film 560. Blocking film 565 may be formed from any suitable material, such as a metal or an insulator. A lithographic mask 570 is then formed overlying the blocking layer 565, as shown in FIG. 19d.

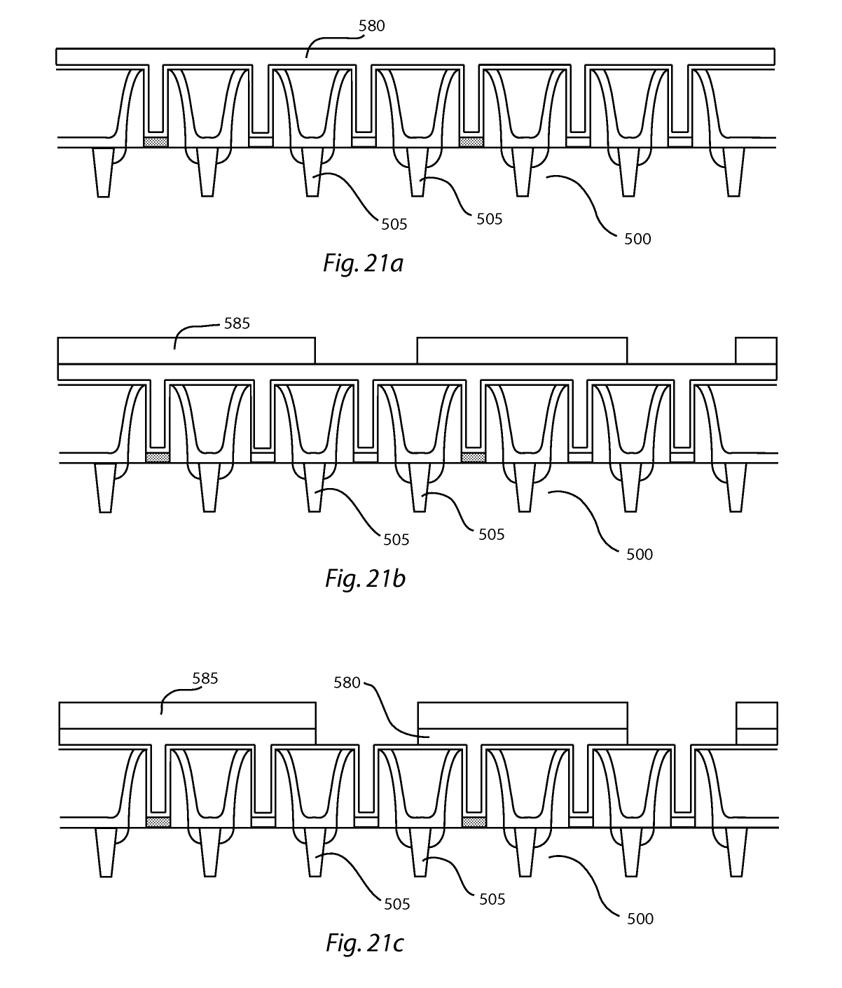

Referring now to FIG. 20a, the regions of blocking film 565 exposed through mask 570 are removed by any suitable process, to reveal regions of the underlying high-K film 560. It will be noted that the edges of the openings in mask 570 are aligned with selected STI elements 505, and that the exposed regions of high-K film 560 overlie two of the six gate stack cavities. Mask 570 is then removed, and the structure depicted in FIG. 20b is subjected to nitridation as described in connection with various of the previous embodiments, to generate nitrided regions 575 of the insulating film 555 in those regions where it is exposed through the openings in blocking film 565. On the other hand, the regions of insulating film 555 that are covered by blocking film 565 are not nitrided. Thus, unnitrided regions 555 will differ in work function from nitrided regions 575. The blocking film 565 is now removed entirely, as shown in FIG. 20c.

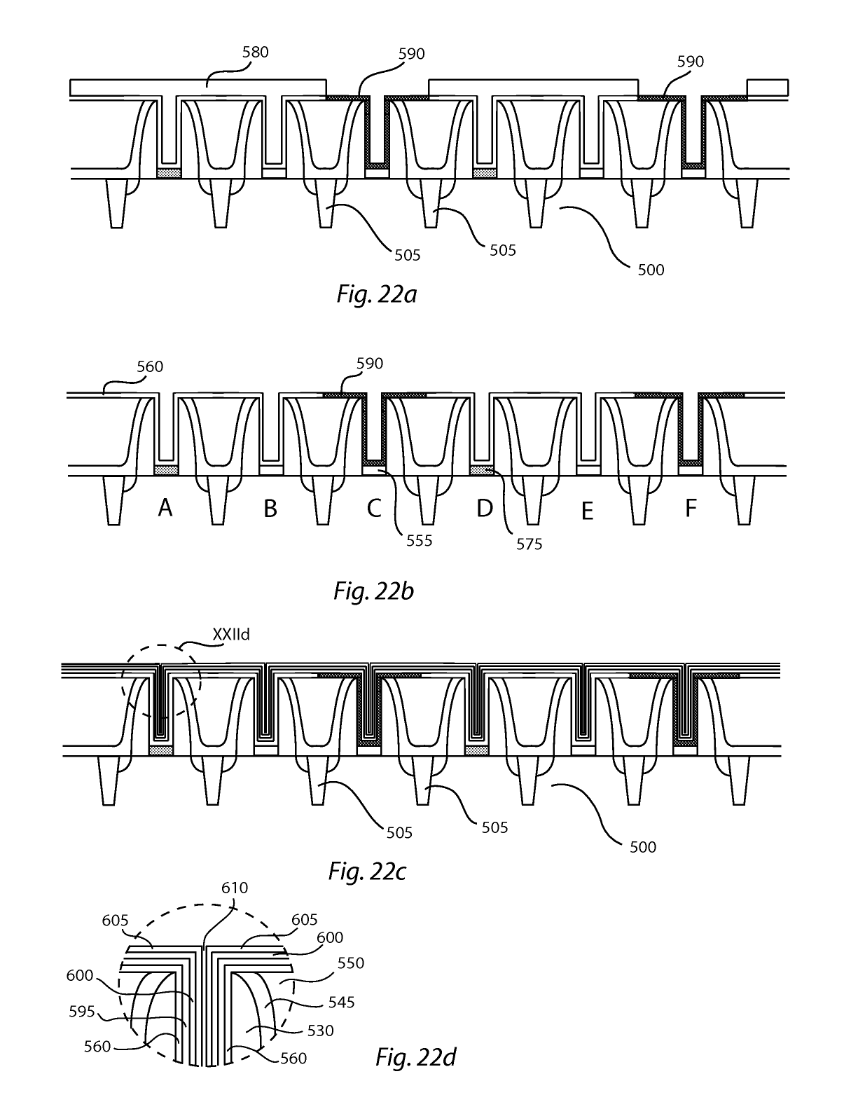

Turning now to FIG. 21a, a fresh layer of blocking film 580 is deposited so as to cover all exposed surfaces shown in the drawing, followed by formation of a new mask 585 (FIG. 21b) whose openings are centered above two of the gate cavities other than those that were nitrided in the preceding steps. Mask 585 is then utilized to remove the regions of underlying blocking film 580 that are exposed through the mask (FIG. 21c), thereby exposing the high-K film 560 in regions overlying the second pair of selected gate cavities.

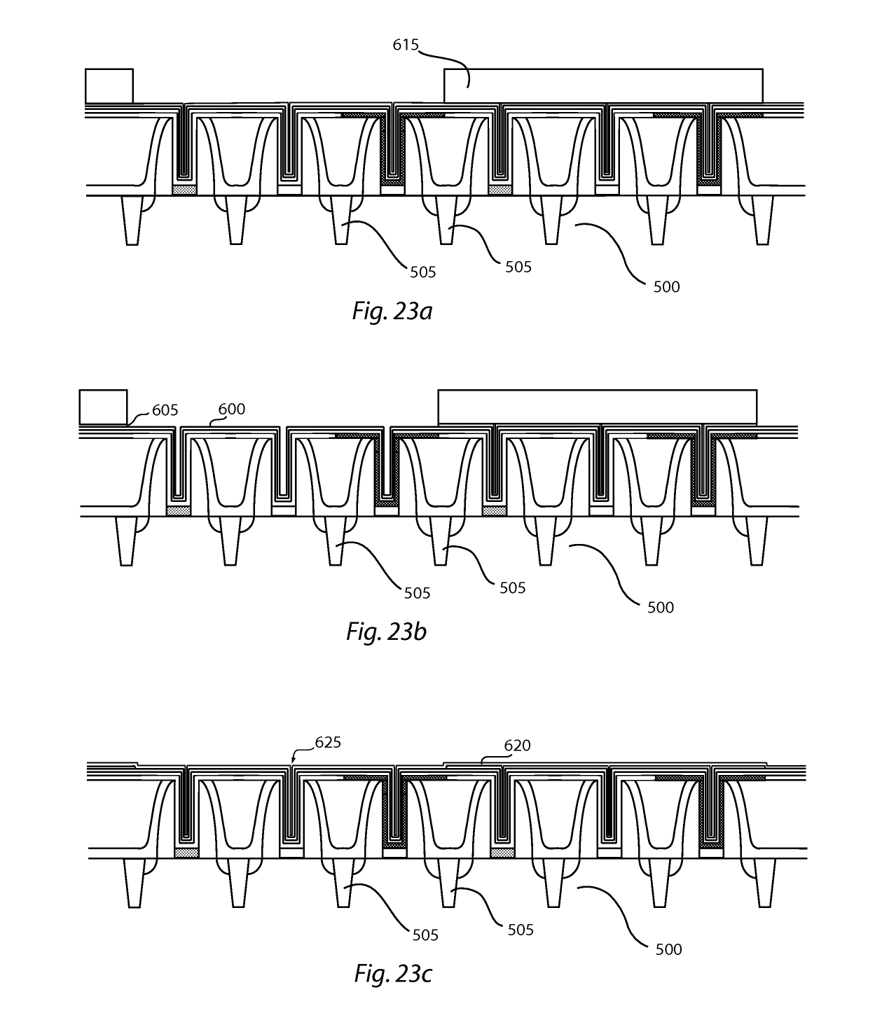

Next, as shown in FIG. 22a, following removal of the mask 585, the regions of high-K film 560 not covered by blocking film 580 regions are subjected to oxidation annealing as described above in connection with FIG. 9b. This serves to produce regions 590 of high-K film 560 whose work function differs from that of the regions of high-K film not so treated. Blocking film 580 is then removed, to produce the structure shown in FIG. 22b.

At this stage, each of the six depicted gate cavities has a partial gate stack formed therein, and the six partial gate stacks already possess three mutually different work functions. That is, the gates A and D have a work function determined by the composite work functions of nitrided insulating film 575 and non-oxidized high-K film 560; the gates B and E have a work function determined by the composite work functions of non-nitrided insulating film 555 and non-oxidized high-K film 560; and the gates C and F have a work function determined by the composite work functions of non-nitrided insulating film 555 and oxidized high-K film 590.

A series of films are then sequentially deposited on the high-K film, namely, a layer of n work function metal 595 as described above in connection with various of the previous embodiments, a metal etch stop layer 600, and a layer of p work function metal 605 as described above in connection with various of the previous embodiments. The resulting structure is shown in FIG. 22c, with an enlarged detail thereof being shown in FIG. 22d. These layers serve to fill the gate cavities except in a narrow central cylindrical opening 610.

Referring now to FIG. 23a, a further mask 615 is formed on the structure depicted in FIG. 22c, so as to cover three of the gate stacks while exposing another three of the gate stacks. Etching is then performed so as to remove the layer of p work function metal 605 only in the regions exposed through mask 615, as shown in FIG. 23b, and to reveal the underlying metal etch stop layer 600 in those regions.

The patterning of the n work function metal and the p work function metal as described in the present application may be performed on these layers directly, or, alternatively, may be performed in the presence of one or more additional layers, for example a layer of titanium nitride (TiN).

Next, as shown in FIG. 23c, following removal of mask 615, a metal layer 620 is deposited so as to cover all of the surfaces exposed as shown in FIG. 22b. This metal layer 620 completes the filling of the gate cavities for the gates where the p work function metal 605 was not removed, whereas in the gates where the p work function metal was removed, a narrow cylindrical cavity 625 remains.

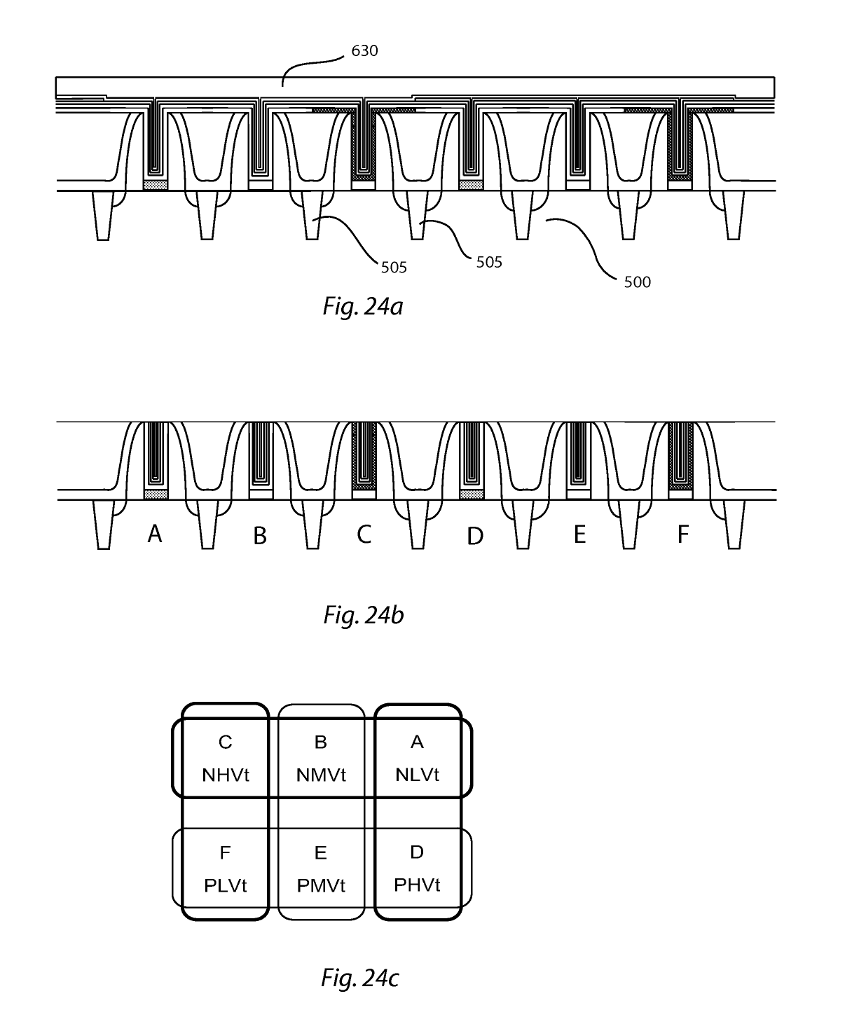

Then, a layer 630 of aluminum is deposited on the structure as shown in FIG. 24a, following which aluminum reflow is performed and excess aluminum is removed by wet etching or CMP as shown in FIG. 24b. As a result, aluminum completes the filling of those gate cavities from which the p work function metal 605 had been removed, and completes the gate stack formation process according to this embodiment.

The gates as depicted in FIG. 24b now possess six mutually different work functions as a result of six different juxtaposed or superposed combinations of two or more materials having respectively different work functions. In particular, gate A has a work function reflecting a composite of the work functions of nitrided insulating film 575, non-oxidized high-K film 560, n work function metal 595, metal 620 and aluminum layer 630; gate B has a work function reflecting a composite of the work functions of non-nitrided insulating film 555, non-oxidized high-K film 560, n work function metal 595, metal 620 and aluminum layer 630; gate C has a work function reflecting a composite of the work functions of non-nitrided insulating film 555, oxidized high-K film 590, n work function metal 595, metal 620 and aluminum layer 630; gate D has a work function reflecting a composite of the work functions of nitrided insulating film 575, non-oxidized high-K film 560, n work function metal 595, p work function metal 605, and metal 620; gate E has a work function reflecting a composite of the work functions of non-nitrided insulating film 555, non-oxidized high-K film 560, n work function metal 595, p work function metal 605, and metal 620; and gate F has a work function reflecting a composite of the work functions of non-nitrided insulating film 555, oxidized high-K film 590, n work function metal 595, p work function metal 605, and metal 620.

As shown in FIG. 24c, this embodiment, as with other embodiments of the invention, permits creating a high number of different gate threshold voltages without a correspondingly high number of lithography processes. The layout of this embodiment is also efficient, wherein the gates A, B and C have a work function influenced by the n work function metal 595 without the influence of p work function metal 605, whereas the gates D, E and F have a work function influenced by both the n work function metal 595 and the p work function metal 605. Furthermore, gates A and F have lower threshold voltages NLVt and PHVt than their counterparts with the same configuration of work function metals; gates B and F have intermediate threshold voltages NMVt and PMVt relative to their counterparts with the same configuration of work function metals; and gates C and D have high threshold voltages NMVt and PMVt relative to their counterparts with the same configuration of work function metals.

While the present invention has been described in connection with various preferred embodiments thereof, it is to be understood that those embodiments are provided merely to illustrate the invention, and should not be used as a pretext to limit the scope of protection conferred by the true scope and spirit of the appended claims.

What is claimed is:

1. A semiconductor device comprising:
a first transistor having a gate stack comprising an underlying layer formed of a first material and an overlying layer formed of a second material;
a second transistor having a gate stack comprising an underlying layer formed of a third material and an overlying layer formed of said second material;
a third transistor having a gate stack comprising an underlying layer formed of said first material and an overlying layer formed of a fourth material; and
a fourth transistor having a gate stack comprising an underlying layer formed of said third material and an overlying material formed of said fourth material;
wherein each of said first through fourth materials has a respectively different work function;
whereby each of said first through fourth transistors has a respectively different threshold voltage.

2. The semiconductor device according to claim 1, wherein the first material is a layer of a nitrided chemical oxide formed on a semiconductor substrate and wherein the third material is a layer of an oxide formed on said semiconductor substrate, the third material being unnitrided or nitrided to a lesser extent than the first material.

3. The semiconductor device according to claim 1, wherein the second material is a layer of an n work function metal and the third material is a layer of a p work function metal.

4. The semiconductor device according to claim 1, wherein the gate stack of the first and third transistors does not include a layer of said third material and wherein the gate stack of the second and fourth transistors does not include a layer of said first material.

5. The semiconductor device according to claim 1, wherein the gate stack of the third and fourth transistors further comprises a layer of said second material.

6. The semiconductor device according to claim 1, wherein said second material is a high-k dielectric layer doped with atoms of an n work function metal and said fourth material is a high-k dielectric layer doped with atoms of a p work function metal.

7. The semiconductor device according to claim 1, wherein said first material is a high-k dielectric layer and said third material is a high-k dielectric layer in which vacancies within said third material are filled by oxygen to a greater extent than in said first material.

8. The semiconductor device according to claim 1, wherein said second material is a high-k dielectric layer and said fourth material is a high-k dielectric layer in which vacancies within said fourth material are filled by oxygen to a greater extent than in said second material.

9. The semiconductor device according to claim 1, further comprising:
a fifth transistor having a gate stack comprising an underlying layer formed of said first material and an overlying layer formed of a fifth material; and
a sixth transistor having a gate stack comprising an underlying layer formed of said third material and an overlying layer formed of said fifth material;
wherein said fifth material has a different work function than each of said first through fourth materials;
whereby each of said first through sixth transistors has a respectively different threshold voltage.

10. The semiconductor device according to claim 9, wherein said second material is a high-k dielectric layer doped with atoms of an n work function metal; said fourth material is a high-k dielectric layer doped with atoms of an n work function metal and a p work function metal; and said fifth material is a high-k dielectric layer doped with atoms of a p work function metal.

11. A semiconductor device comprising:
a plurality of transistors each having a high-k dielectric layer underlying a gate and overlying a semiconductor substrate;
a first group of said high-k dielectric layers being doped with atoms of an n work function metal, and a second group of said high-k dielectric layers being doped with atoms of a p function work metal;
a first subset of each of said first and second groups of high-k dielectric layers having vacancies that are filled by oxygen to a greater extent than in a second subset of each of said first and second groups of high-k dielectric layers;
whereby each of said plurality of transistors comprises a high-k dielectric layer having one of at least four mutually different work functions.

12. A method of making a semiconductor device, comprising:
depositing a layer of a first material on a semiconductor substrate;
modifying selected portions of the first material to create regions of a second material adjoining regions of said first material;
depositing a layer of a third material overlying the layer of first material;
modifying selected portions of the third material to create regions of a fourth material adjoining regions of said third material;
wherein the regions of fourth material and the regions of third material each separately overlap both the regions of first and second material, and wherein the first through fourth materials have respectively different work functions; and
etching the layers to isolate gate stack structures each comprising one of the first and second materials as a lower layer and one of the third and fourth materials as an upper layer.

13. The method according to claim 12, wherein the third material is a high-k dielectric layer doped with atoms of an n work function metal.

14. The method according to claim 12, wherein the fourth material is a high-k dielectric layer doped with atoms of a p work function metal.

15. The method according to claim 12, wherein said first material is a high-k dielectric layer and said second material is a high-k dielectric layer in which vacancies within said second material are filled by oxygen to a greater extent than in said first material.

16. The method according to claim 12, wherein said third material is a high-k dielectric layer and said fourth material is a high-k dielectric layer in which vacancies within said fourth material are filled by oxygen to a greater extent than in said third material.

17. A method of making a semiconductor device, comprising:
depositing a region of each of q materials on a semiconductor substrate, wherein q is an integer of 2 or 3;
depositing a region of each of r materials overlying the regions of m materials, wherein r is an integer of 2 or 3;
wherein each of the q materials and each of the r materials has a respectively different work function from all others of the q and r materials;
wherein only one of q and r may equal three; and
etching the regions of the q and r materials to form transistor gate stacks each comprising an underlying q material layer and an overlying r material layer;
thereby to create transistor gates having at least four threshold voltages.

18. The method according to claim 17, wherein one of q and r is 3, thereby to create transistor gates having at least four threshold voltages.

19. The method according to claim 17, further comprising:
depositing a region of each of s materials separately overlying the regions of q and r materials, wherein s is an integer of 2 or 3;
thereby to create transistor gates having at least eight threshold voltages.
